(19) United States
(12) Patent Application Publication
(10) Pub. No.: US 2010/0322410 A1
(43) Pub. Date: Dec. 23, 2010

(54) Electronic Device Having a Display Screen

(75) Inventors: Cheng-Hsuan LIN, Hsichih (TW); Yung-Feng LIN, Hsichih (TW); Mei-Hui CHEN, Hsichih (TW)

Correspondence Address: STEPTOE & JOHNSON LLP, 1330 CONNECTICUT AVENUE, N.W., WASHINGTON, DC, 20036, US

(73) Assignee: Wistron Corporation, Hsichih (TW)

(21) Appl. No.: 12/816,015

(22) Filed: Jun. 15, 2010

(30) Foreign Application Priority Data
Jun. 17, 2009 (TW) 098120265

(51) Int. Cl. H04M 1/00; H05K 7/00

(52) U.S. Cl. 379/428.03; 361/679.01

(57) ABSTRACT

An electronic device includes a base and a display screen. The base includes an upper surface and a plurality of spaced-apart positioning members disposed on the upper surface. The display screen includes a screen body, and a support member connected pivotably to a rear face of the screen body and rotatable relative to the screen body. The support member has one end connected to the screen body, and an opposite end engageable with a selected one of the positioning members so as to support and position the screen body stably at a selected angular position.

### CROSS-REFERENCE TO RELATED APPLICATION

This application claims priority of Taiwanese Application No. 098120265, filed on Jun. 17, 2009.

### BACKGROUND OF THE INVENTION

1. Field of the Invention

The invention relates to an electronic device, more particularly to an electronic device that has a display screen which permits angle adjustment.

2. Description of the Related Art

A conventional desktop type Internet-based or VoIP (Voice over Internet Protocol) telephone includes a phone device and a display screen disposed on the phone device for displaying video images. One such telephone is disclosed in Taiwanese Utility Model No. M300400.

However, the display screen of the Internet-based telephone disclosed in the aforesaid patent is secured directly to the phone device, and the angle of the display screen is not adjustable, so that it is relatively inconvenient to view the images di splayed on the display screen. Therefore, how to devise an Internet-based telephone structure with a display screen whose angle is adjustable relative to a phone device and which can be positioned stably at an inclined position after angle adjustment is the subject of improvement of the present invention.

### SUMMARY OF THE INVENTION

Therefore, the primary object of the present invention is to provide an electronic device that has a display screen which permits angle adjustment and which can be positioned stably at a selected angular position.

Another object of the present invention is to provide an electronic device that has a display screen which can be retained stably on a base of the electronic device when disposed in a closed state.

A further object of the present invention is to provide an electronic device that has a display screen including a panel and a casing which are coupled by snap-fit engagement to enable the panel to be assembled to or removed from the casing in a quick and convenient manner so as facilitate replacement of the panel with one of a different design.

The objects of this invention and solutions to the technical problems associated with the prior art are realized using the following technical means. The electronic device of the present invention comprises a base and a display screen.

The base includes an upper surface, and a plurality of positioning members disposed on the upper surface and spaced apart from one another. The display screen includes a screen body which has one end connected pivotably to the base and which is rotatable relative to the base, and a support member connected pivotably to a rear face of the screen body and rotatable relative to the screen body. The support member has one end connected to the rear face of the screen body, and an opposite end engageable with a selected one of the positioning members so as to support and position the screen body at an inclined position.

In the aforementioned electronic device, one end of the support member is connected pivotably to the screen body, and each of the positioning members is a stop block projecting from the upper surface of the base. The support member includes a projecting block for engaging the selected one of the positioning members. The support member can engage the selected positioning member in a stable manner.

In the aforementioned electronic device, the base defines an operation path and a restoring path disposed above and in spatial communication with the operation path. The support member includes a guide post movable between the operation path and the restoring path. The guide post is positioned in the operation path when the support member is engaged with the selected one of the positioning members. The base further includes a resilient plate disposed at front ends of the operation and restoring paths to provide the guide post with a spring force to spring upwardly to the restoring path. Thus, the guide post can move smoothly from the operation path to the restoring path.

In the aforementioned electronic device, the base further includes two sidewalls extending upwardly and respectively from two opposite sides of the upper surface, and two first engaging members disposed respectively on the sidewalls. The screen body includes two second engaging members disposed on two opposite sides thereof. Each of the second engaging members is engageable removably with a respective one of the first engaging members to posit ion the screen body between the sidewalls Each of the first engaging members is one of a curved engaging block and a curved engaging groove, and each of the second engaging members is the other of the curved engaging block and the curved engaging groove. Thus, the screen body can be retained stably on the base when the screen body is at the closed position, so that rubbing or scratching between the screen body and the base resulting from wobbling of the base when the base is being moved can be prevented.

In the aforementioned electronic device, the screen body includes a casing connected pivotably to the support member, and a panel coupled to and covering the casing. The casing includes a plurality of first hooks disposed on an outer periphery thereof. The panel includes a plurality of second hooks disposed on an outer periphery thereof. Each of the second hooks is engageable removably with a respective one of the first hooks.

In the aforementioned electronic device, the screen body includes a casing connected pivotably to the support member, and a panel coupled to and covering the casing. The casing has one side provided with a plurality of U-shaped anchoring members projecting outwardly therefrom, and an opposite side provided with a plurality of first hooks. The panel has one side provided with a plurality of positioning hooks, and an opposite side provided with a plurality of second hooks. Each of the positioning hooks is engageable removably with a bottom end of a respective one of the anchoring members. Each of the second hooks is engageable removably with a respective one of the first hooks. Thus, the panel can be quickly assembled to or removed from the casing to facilitate replacement of the panel with one of a different design.

In the aforementioned electronic device, the screen body further includes a keypad module assembled to an inner surface of the panel. The panel has a plurality of through holes. The keypad module includes a plurality of keys corresponding in number to the through holes and extending respectively through the through holes. Thus, replacement of the panel and the keypad module can be quickly conducted to enhance design flexibility and lower manufacturing costs.

In the aforementioned electronic device, the display screen further includes a torsion spring disposed on the rear face of the screen body. The torsion spring has two ends respectively abutting against the rear face of the screen body and the support member so that the support member and the screen body form an angle therebetween. Thus, when the screen body is rotated relative to the base to adjust the angle of the screen body, the support member will not collapse and rub against the upper surface of the base.

In the electronic device of the present invention, due to the configuration of the positioning members on the upper surface of the base, the support member can engage a selected one of the positioning members to support and position the screen body stably at an inclined position. Furthermore, by virtue of the design of the first and second engaging members, the screen body can be secured stably on the base when in a closed state. In addition, through the arrangement of the positioning hooks and the first hooks on the panel that respectively engage the anchoring members and the second hooks on the casing, the panel can be quickly assembled to or removed from the casing to permit easy replacement of the panel with one of a different design.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of a preferred embodiment of an electronic device having a display screen according to the present invention;

FIG. 2 is a perspective view of the preferred embodiment when viewed from another angle, illustrating a screen body supported and positioned by a support member at an inclined position;

FIG. 3 is an exploded perspective view of the preferred embodiment, illustrating the arrangement relationship between a base and the display screen;

FIG. 4 is a perspective view to illustrate the base of the preferred embodiment;

FIG. 5 is an exploded perspective view to illustrate the display screen of the preferred embodiment;

FIG. 6 is a schematic view to illustrate a slide block of a second pivot member that is slidable along a curved slide groove of a first pivot member;

FIG. 7 is a sectional view taken along line 7-7 of FIG. 1, illustrating snap-fit engagement between a first engaging member in the form of a curved engaging block and a second engaging member in the form of a curved engaging groove;

FIG. 8 is a sectional view similar to FIG. 7, but showing the first engaging member to be a curved engaging groove and the second engaging member to be a curved engaging block;

FIG. 9 is a sectional view taken along line 9-9 of FIG. 1, showing a guide post of the support member at an initial position of an operation path when the screen body is at a closed position;

FIG. 10 is a schematic side view of the preferred embodiment to illustrate how the screen body can be supported by the support member at three different slanting positions of varying angles;

FIG. 11 is a sectional view similar to FIG. 9, but showing changes in the position of the guide post of the support member when the screen body is positioned at the different slanting positions;

FIG. 12 is a fragmentary schematic sectional view of the preferred embodiment, illustrating how a resilient plate provides the guide post with a spring force to enable the guide post to spring upwardly from the operation path to the restoring path;

FIG. 13 is an exploded perspective view of the screen body of the preferred embodiment;

FIG. 14 is an exploded perspective view of the screen body of the preferred embodiment when viewed from another angle;

FIG. 15 is a sectional view of the screen body of the preferred embodiment to illustrate engagement between positioning hooks and bottom ends of anchoring members and snap-fit engagement between first and second hooks;

FIG. 16 is a sectional view of the screen body of the preferred embodiment to further illustrate the snap-fit engagement between the first and second hooks; and

FIG. 17 is a fragmentary sectional view of the screen body of the preferred embodiment to illustrate the structure of a keypad module.

### DETAILED DESCRIPTION OF THE PREFERRED EMBODIMENT

Through a description of the preferred embodiment, the technical means employed by the present invention to achieve the intended objects, and the advantageous effects contemplated thereby, can be better understood and appreciated. It is noted that the accompanying drawings are for illustration and reference only, and are not intended to limit the scope of the present invention.

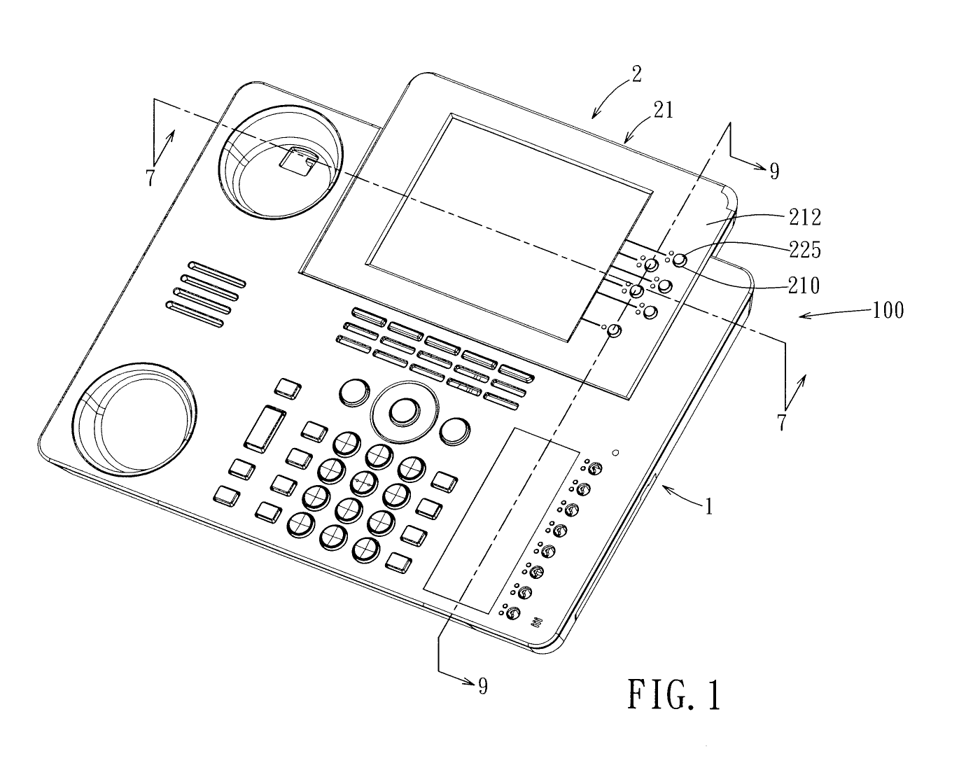

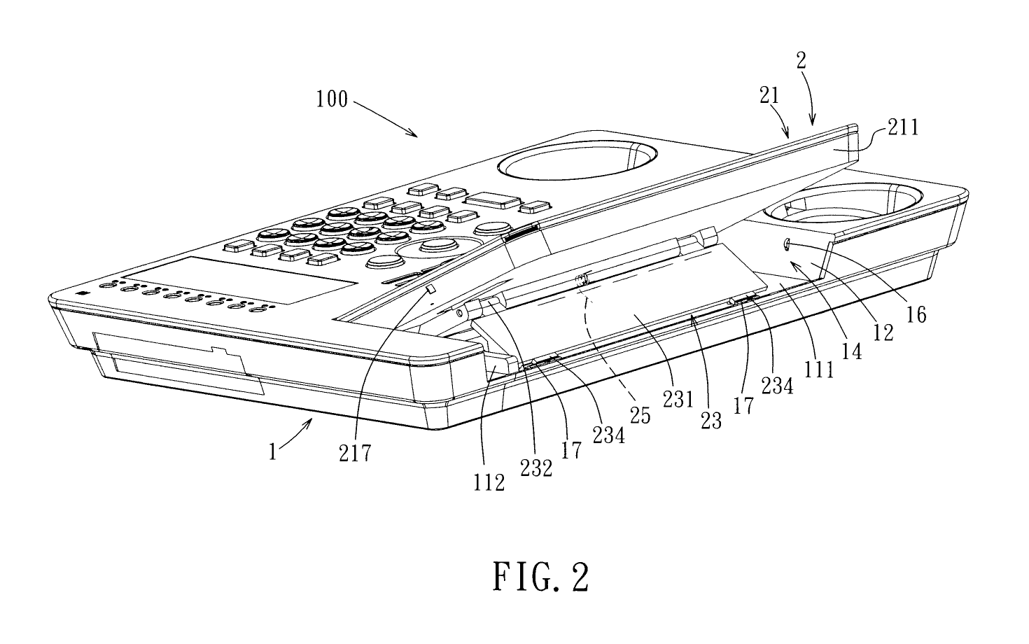

Referring to FIGS. 1 and 2, the preferred embodiment of an electronic device 100 according to the present invention is exemplified to be a desktop type Internet-based telephone, and includes a base 1 and a display screen 2 connected pivotably to the base 1. Certainly, the electronic device 100 may be a facsimile machine or any type of communications device.

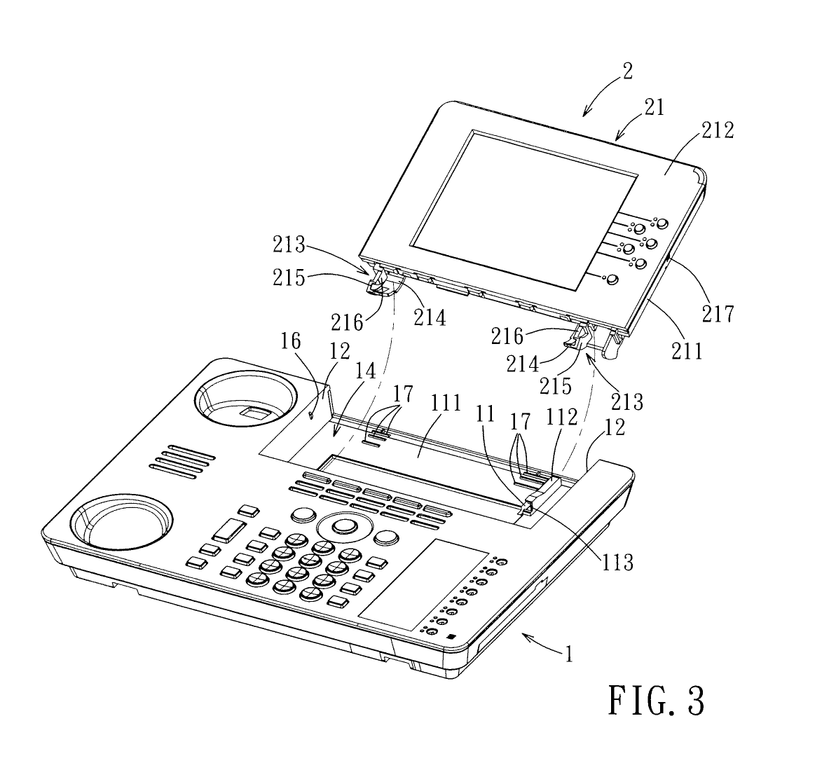

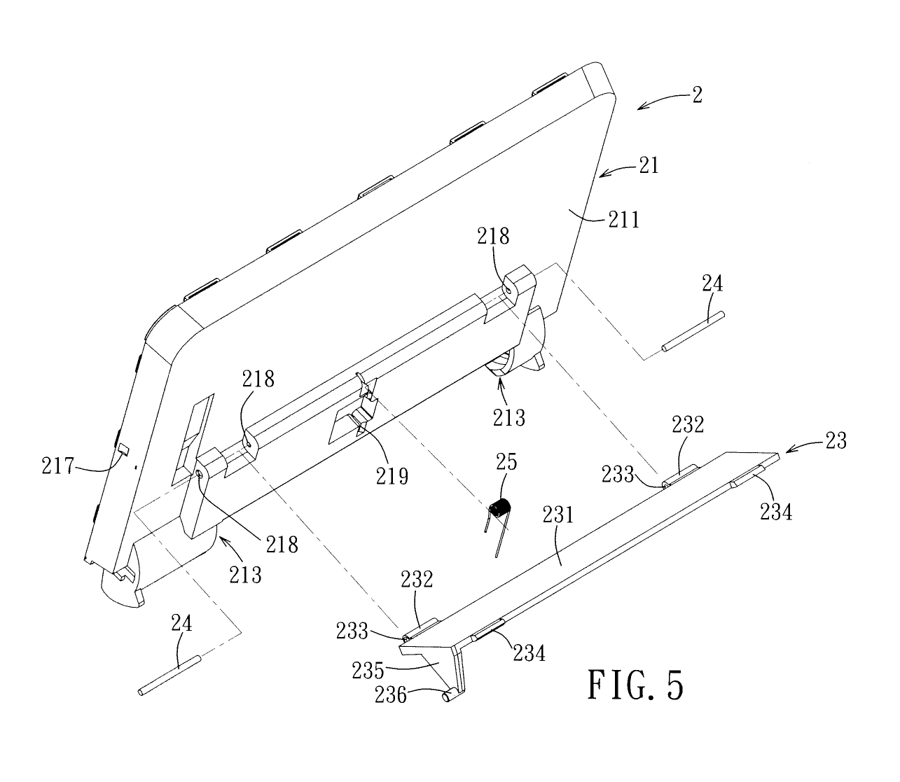

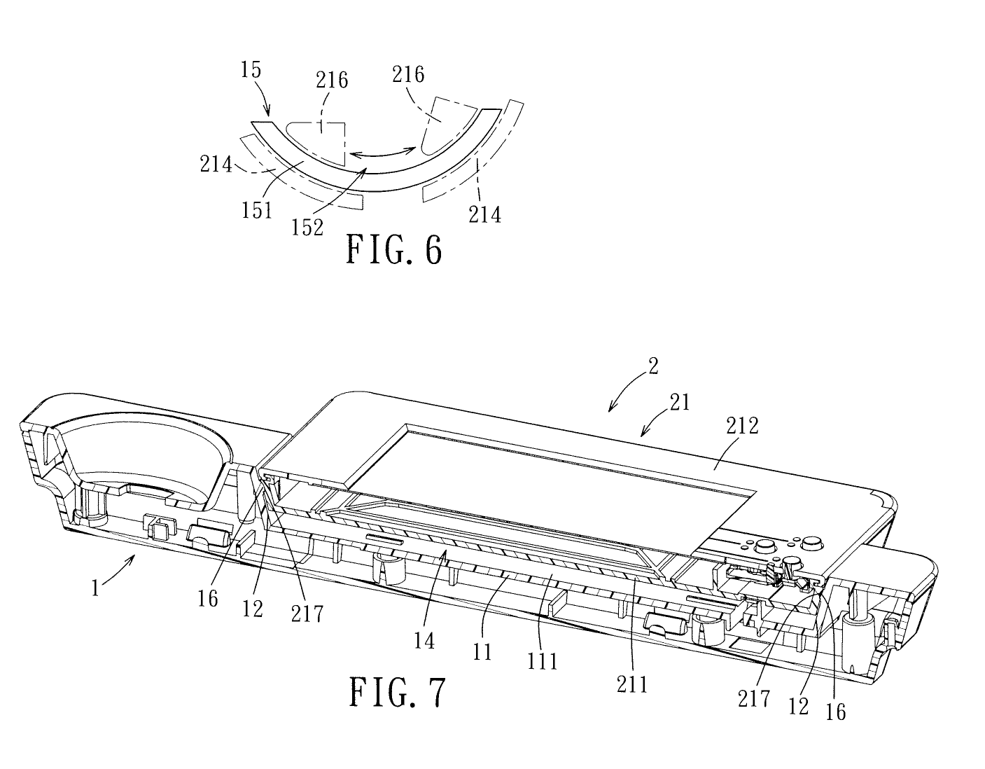

Referring to FIGS. 3, 4, and 5, the base 1 includes a base wall 11, two sidewalls 12 extending upwardly and respectively from opposite left and right sides of an upper surface 111 of the base wall 11, and a front wall 13 formed at a front end of the base wall 11 and connected to the two sidewalls 12. The base wall 11, the sidewalls 12, and the front wall 13 cooperatively define a receiving space 14 for receiving the display screen 2 and having open top and rear ends. The front wall 13 is provided with two spaced-apart openings 131. The base 1 further includes two first pivot members 15 extending respectively through the two openings 131. Each of the first pivot members 15 includes a curved plate 151. The curved plate 151 defines a curved slide groove 152 disposed at a top end thereof. The display screen 2 includes a substantially rectangular screen body 21. The screen body 21 includes a casing 211, and a panel 212 removably coupled to and covering the casing 211. The casing 211 is provided with two second pivot members 213 projecting from a front side thereof and corresponding respectively to the first pivot members 15 in position. Each of the second pivot members 213 includes a curved plate 214, a side plate 215 formed at an outer side of the curved plate 214, and a slide block 216 extending inwardly from the side plate 215. Through the curved plate 214 of each of the second pivot members 213 that abuts against a bottom side of the curved plate 151 of a respective one of the first pivot members 15, and through the slide blocks 216 which engage slidably and respectively the curved slide grooves 152, the screen body 21 is rotatable within a predetermined angle relative to the first pivot members 15 of the base 1 through the second pivot members 213, as shown in FIG. 6.

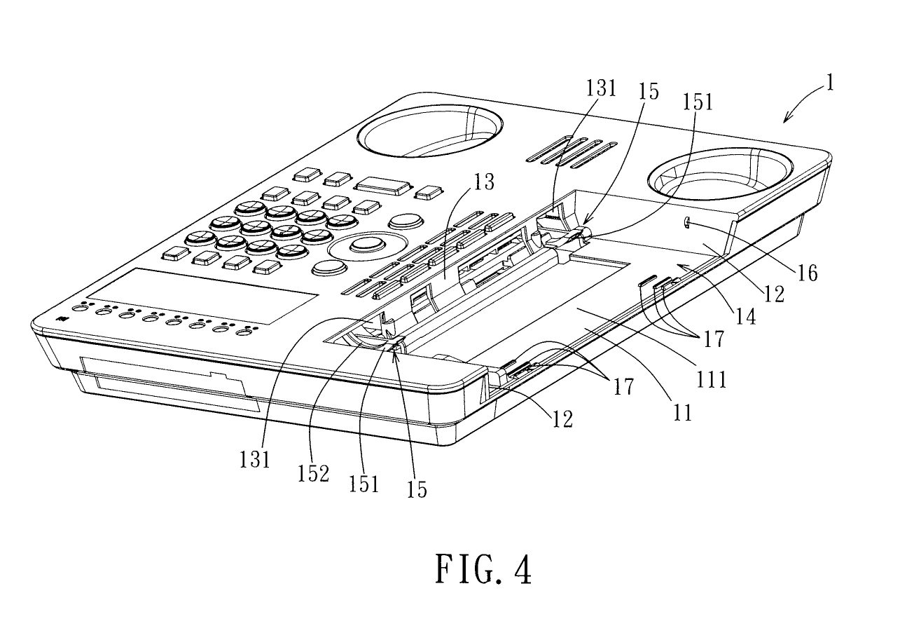

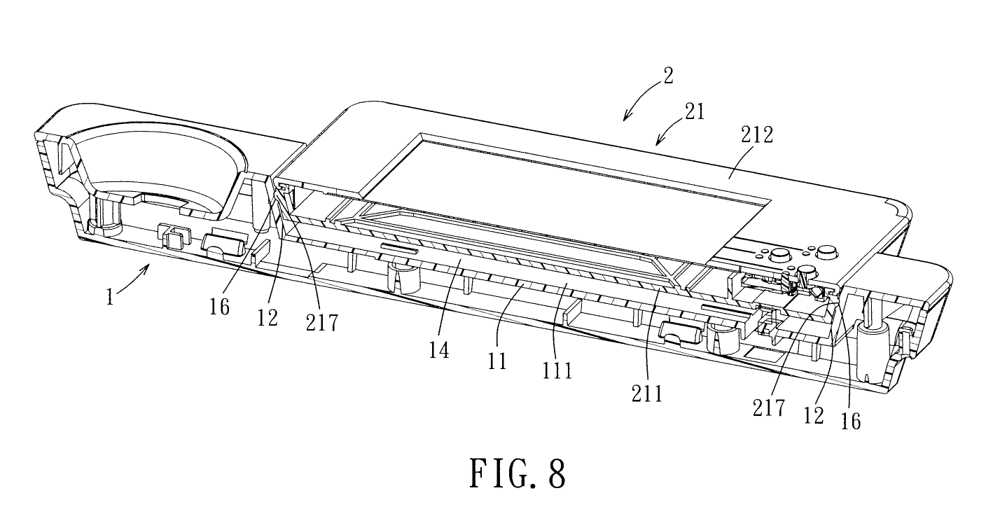

Referring to FIGS. 4, 5 and 7, the base 1 further includes two first engaging members 16 disposed respectively on the two sidewalls 12. The casing 211 of the screen body 21 further includes two second engaging members 217 disposed respectively on opposite left and right sides thereof. The second engaging members 217 correspond respectively to the first engaging members 16 in position. In this embodiment, each of the first engaging members 16 is a curved engaging block. Each of the second engaging members 217 is a curved engaging groove for engaging releasably a respective one of the first engaging members 16. When the screen body 21 of the display screen 2 is disposed at a closed position within the receiving space 14, through the engagement between the second engaging members 217 and the first engaging members 16, the screen body 21 can be positioned stably in the receiving space 14 when in a non-rotated state. Thus, rubbing or scratching between the screen body 21 and the base 1 resulting from wobbling of the base 1 when the base 1 is being moved can be prevented. It is noted that, alternatively, the first engaging members 16 may be configured to be curved engaging grooves while the second engaging members 217 may be configured to be curved engaging blocks to releasably and respectively engage the first engaging members 16, as shown in FIG. 8.

Referring to FIGS. 2, 3, 4, and 5, the base wall of the base 1 further includes a plurality of positioning members 17 disposed on the upper surface 111. In this embodiment, every three positioning members 17 are arranged in a set, and there are two sets of the positioning members 17, which are spaced apart with one on the left, the other on the right. The three positioning members 17 in each set are spaced apart in a front-rear direction. Each of the positioning members 17 is in the form of an elongated stop block projecting from the upper surface 111. The display screen 2 further includes a support member 23 connected pivotably to a rear face of the casing 211 of the screen body 21. The support member 23 includes a substantially rectangular plate 231, and two spaced-apart pivot portions 232 disposed on one end of the plate 231. Each of pins 24 is extended through corresponding ones of pivot holes 218 provided in the rear face of the casing 211 and a pivot hole 233 formed in a respective one of the pivot portions 232 so as to enable the support member 23 to be connected pivotably to the rear face of the casing 211 and to be rotatable relative to the screen body 21. In addition, the other end of the plate 231 of the support member 23 opposite to the end with the pivot portions 232 is provided with two spaced-apart projecting blocks 234. Each of the projecting blocks 234 is engageable with a selected one of the positioning members 17 in a corresponding set. Thus, the screen body 21 can be supported and positioned by the support member 23 at an inclined position (as shown in FIG. 2).

The display screen 2 further includes a torsion spring 25 disposed on the rear face of the casing 211 of the screen body 21. The torsion spring 25 has one end engaging a retaining groove 219 provided in the rear face of the casing 211, and the other end abutting against the plate 231 of the support member 23 so that the support member 23 can form an angle with the casing 211 of the screen body 21 when an external force is not applied thereto. Thus, when the screen body 21 is being rotated relative to the base 1 to adjust the angle of the screen body 21, the support member 23 will not collapse and rub against the upper surface 111.

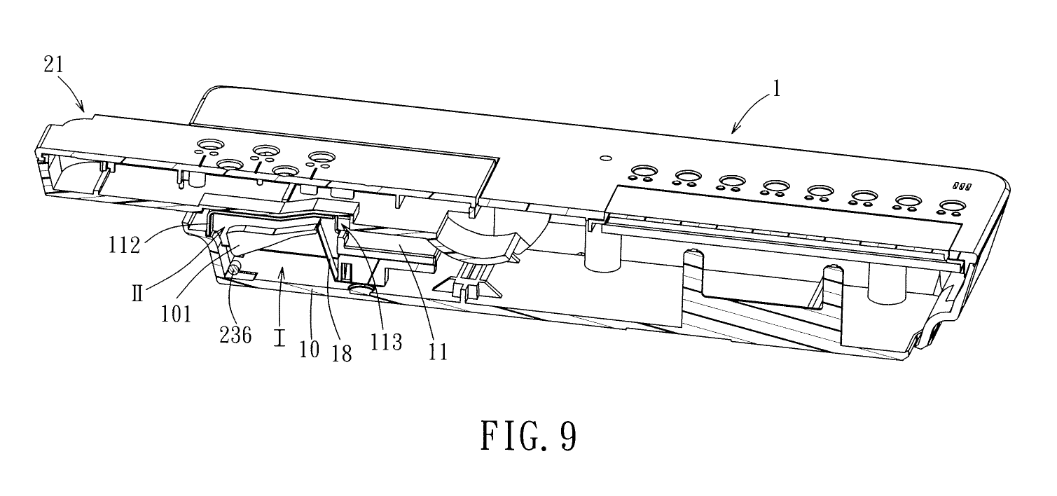

Referring to FIGS. 3, 4, 5, and 9, the upper surface 111 of the base wall 11 is provided with a mounting cover 112 projecting therefrom. The base 1 further includes a bottom shell 10 assembled to a lower side of the base wall 11. A spacer 101 is disposed within the bottom shell 10 below the mounting cover 112. The bottom shell 10, the spacer 101, and the mounting cover 112 cooperatively define an operation path (I) that is disposed below the spacer 101, and a restoring path (II) that is disposed above the spacer 101 and that is in spatial communication with the operation path (I). The support member 23 further includes a side plate 235 connected to a lateral edge of the plate 231, and a guide post 236 projecting outwardly from an outer surface of the side plate 235. The guide post 236 of the support member 23 can be mounted within the bottom shell 10 through an opening 113 in a front end of the mounting cover 112, and the guide post 236 of the support member 23 is movable between the operation path (I) and the restoring path (II). When the screen body 21 of the display screen 2 is at the closed position, the guidepost 236 of the support member 23 is located at an initial position at a rear end of the operation path (I) as shown in FIG. 9.

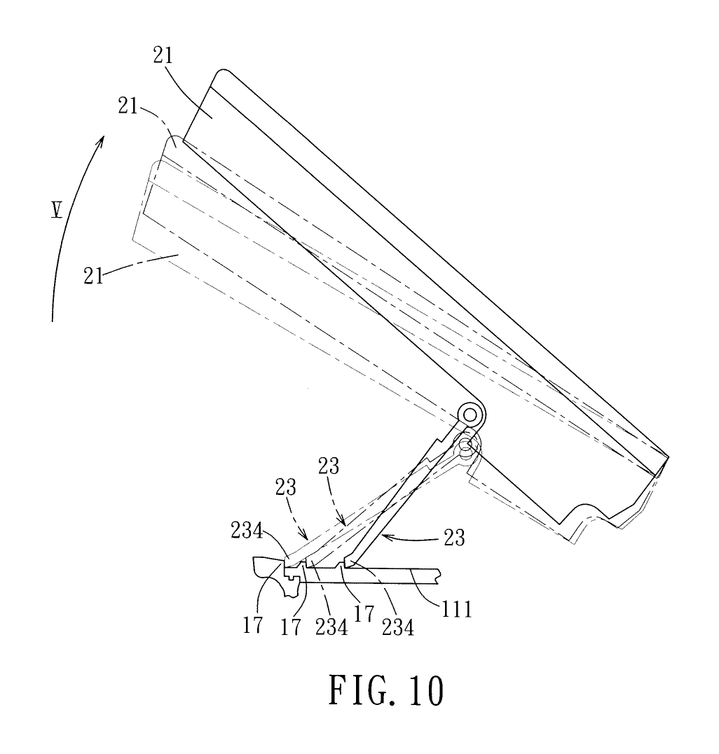

Referring to FIGS. 7 and 10, since the second engaging members 217 of the casing 211 are respectively engaged with the first engaging members 16 of the base 1 when the screen body 21 is at the closed position, when a user wishes to adjust the angle of the screen body 21, the user needs to apply a force to pull a rear end of the screen body 21 upwardly. Since the first engaging members 16 are curved engaging blocks and the second engaging members 217 are curved engaging grooves matching the shape of the curved engaging blocks, after the user has gently pulled the rear end of the screen body 21 upward, the second engaging members 217 can be respectively disengaged from the first engaging members 16 to release an interlocking state between the screen body 21 and the base 1. The user can then rotate the screen body 21 in a direction indicated by arrow (V) (see FIG. 10). The screen body 21 will be supported and positioned by the support member 23 at an inclined position when the user has the projecting blocks 234 of the support member 23 engaging selected ones of the positioning members 17. In this embodiment, when each of the projecting blocks 234 of the support member 23 engages a rearmost one of the three positioning members 17 in the respective set, this indicates that the screen body 21 is positioned at an inclined position in which the screen body 21 is at an angle of 28 degrees to the upper surface 111. When each of the projecting blocks 234 of the support member 23 engages a middle one of the three positioning members 17 in the respective set, this indicates that the screen body 21 is positioned at an inclined position in which the screen body 21 is at an angle of 32 degrees to the upper surface 111. When each of the projecting blocks 234 of the support member 23 engages a foremost one of the three positioning members 17 in the respective set, this indicates that the screen body 21 is positioned at an inclined position in which the screen body 21 is at an angle of 40 degrees to the upper surface 111.

It is noted that the angle between the screen body 21 and the upper surface 111 is determined by the length of the support member 23 and the positions of the positioning members 17 on the upper surface 111. Therefore, in design, the length of the support member 23 and the positions of the positioning members 17 can be modified depending on requirements. Furthermore, the number of the positioning members 17 may be changed according to design requirements so that the screen body 21 can be positioned at more than or less than the three angular positions as exemplified in this embodiment.

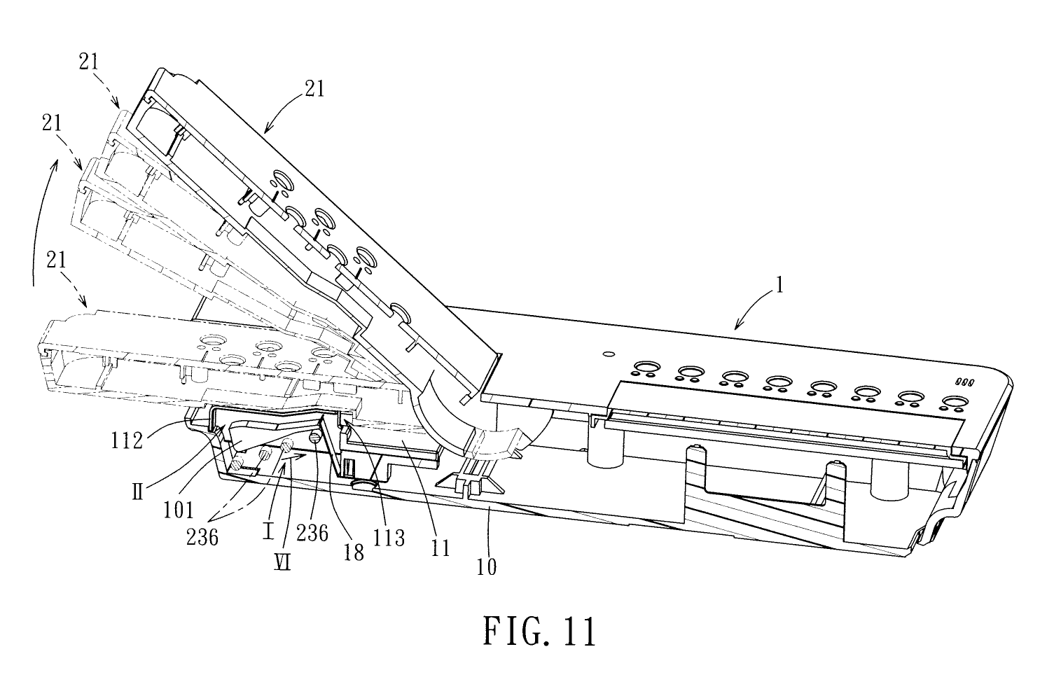

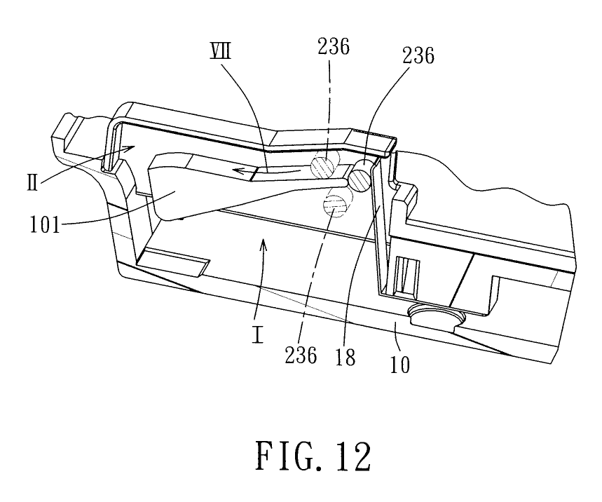

Referring to FIGS. 9, 10, 11, and 12, when the screen body 21 is rotated relative to the base 1 in the direction indicated by arrow (V) (see FIG. 10), the guide post 236 of the support member 23 will move from the initial position shown in FIG. 9 along the operation path (I) in a direction indicated by arrow (VI) (see FIG. 11). The guide post 236 of the support member 23 will be located at one of three different positions (forwardly of the initial position) along the operation path (I) as shown in FIG. 11 when each of the projecting blocks 234 of the support member 23 is engaged with one of the three positioning members 17 in the respective set. The base 1 further includes a resilient plate 18 secured to the bottom shell 10. The resilient plate 18 is disposed at front ends of the operation path (I) and the restoring path (II), and abuts against the spacer 101. Moreover, the resilient plate 18 blocks the front end of the operation path (I). When it is desired to bring the screen body 21 to the closed position from an inclined position in which the screen body 21 is at a largest angle to the upper surface 111, the screen body 21 is rotated a suitable angle along the direction indicated by arrow (V) so as to cause the guide post 236 of the support member 23 to displace forwardly and push the resilient plate 18 forwardly, the resilient plate 18 will impart the guidepost 236 with a spring force to spring upward to the restoring path (II), so that the guide post 236 can move smoothly from the operation path (I) to the restoring path (II). Subsequently, by rotating the screen body 21 downwardly in a direction opposite to that of arrow (V) to the closed position, the guide post 236 will move along the restoring path (II) along a direction indicated by arrow (VII) as shown in FIG. 12 and return to the initial position as shown in FIG. 9.

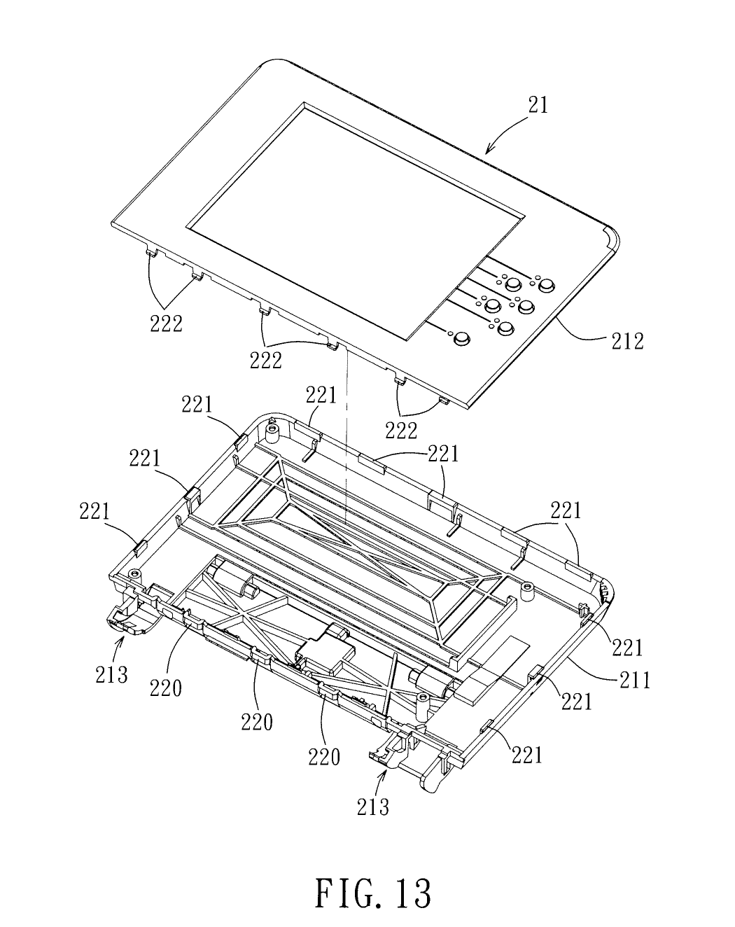

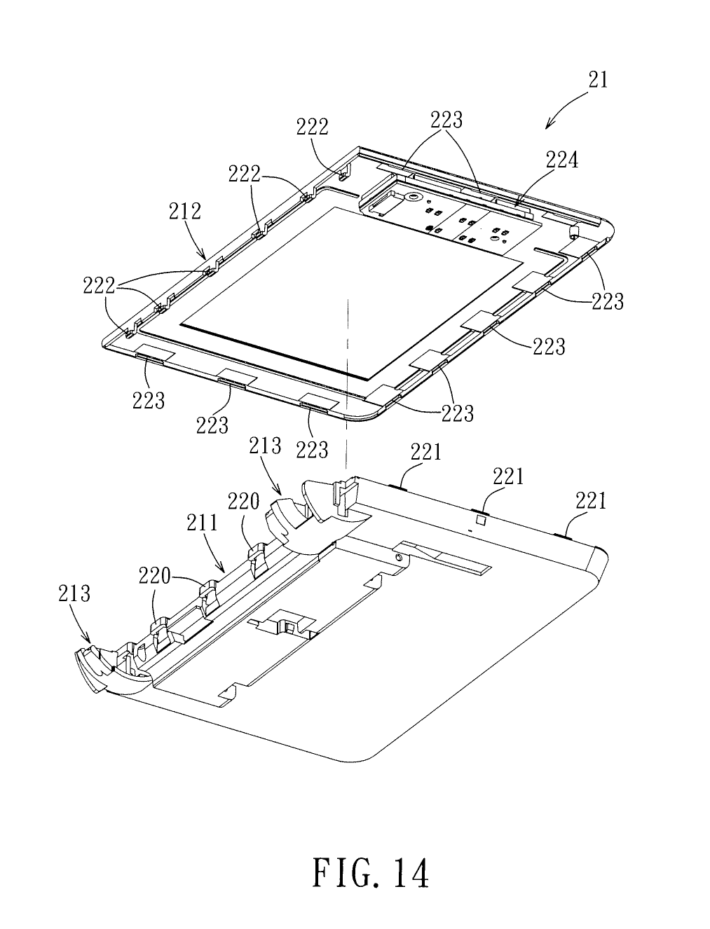

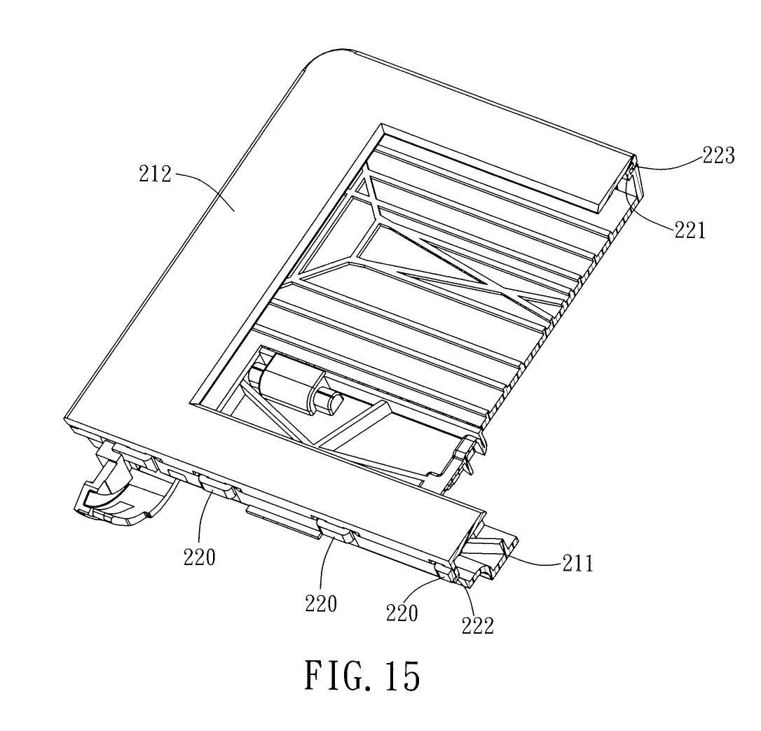

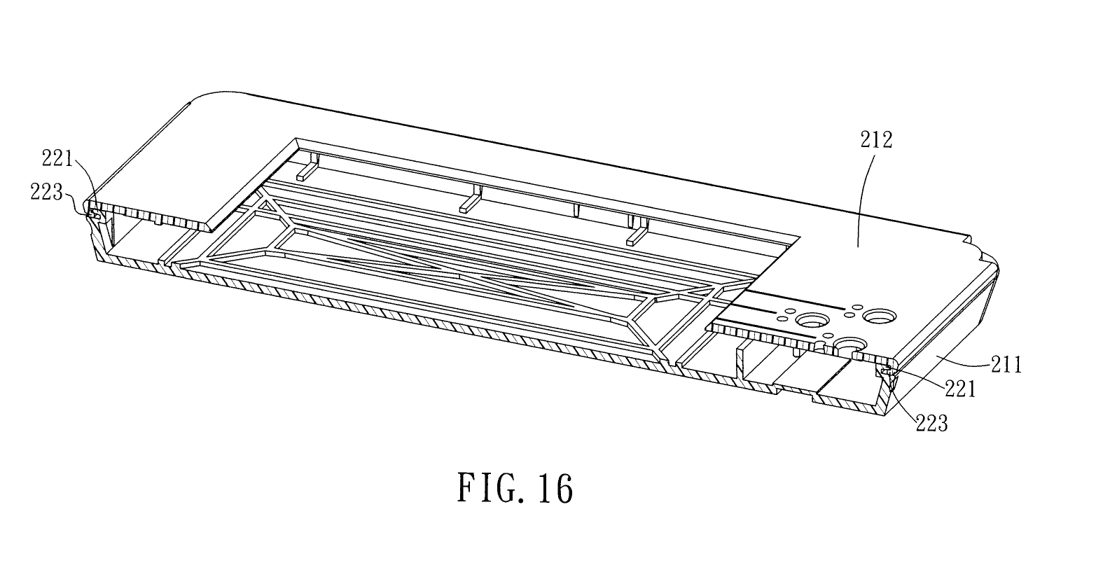

Referring to FIGS. 13, 14, 15, and 16, a plurality of spaced-apart U-shaped anchoring members 220 are disposed on and extend outwardly of the front side of the casing 211 of the screen body 21. A plurality of first hooks 221 are provided along an outer peripheral edge of the casing 211 on left, right, and rear sides thereof in a spaced-apart relationship. A front side of the panel 212 is provided with a plurality of spaced-apart positioning hooks 222. The positioning hooks 222 correspond to the anchoring members 220 in number and position. The positioning hooks 222 are engageable removably and respectively with the anchoring members 220. A plurality of second hooks 223 are provided along an outer peripheral edge of the panel 212 on left, right and rear sides thereof in a spaced-apart relationship. The second hooks 223 correspond to the first hooks 221 in number and position. The second hooks 223 can be brought into snap-fit engagement with the first hooks 221 removably and respectively. Each of the positioning hooks 222 has a longitudinal length greater than that of each of the second hooks 223, so that each of the positioning hooks 222 can engage a bottom end of a respective one of the anchoring members 220.

When it is desired to assemble the panel 212 to the casing 211, the positioning hooks 222 are brought respectively into engagement with the bottom ends of the anchoring members 220, and the second hooks 223 are subsequently brought into snap-fit engagement with the first hooks 221, respectively, thereby completing assembly of the panel 212 to the casing 211. When it is desired to remove the panel 212 from the casing 211, the second hooks 223 are pulled outwardly to be released from positions of engagement with the first hooks 221, respectively, and the positioning hooks 222 are then separated from the bottom ends of the anchoring members 220, thereby completing removal of the panel 212. By configuring the panel 212 and the casing 211 to be coupled by snap-fit engagement, time and costs associated with use of screws and installation of the screws can be saved. Moreover, the panel 212 can be quickly assembled to or removed from the casing 211. Thus, the panel 212 can be easily replaced by a panel of a different design (e.g., of a different shape or color). It is noted that, in design, the first hooks 221 may be provided only on the rear side of the casing 211, and a corresponding number of the second hooks 223 may be provided only on the rear side of the panel 212 at corresponding positions to enable the panel 212 to be coupled to the casing 211 by means of the positioning hooks 222 that respectively engage the anchoring members 220 and the second hooks 223 that respectively engage the first hooks 221. Alternatively, in design, the anchoring members 220 on the casing 211 may be dispensed with, and the positioning hooks 222 on the panel 212 may be correspondingly dispensed with as well, so that the panel 212 is coupled to the casing 211 through the second hooks 223 that respectively engage the first hooks 221.

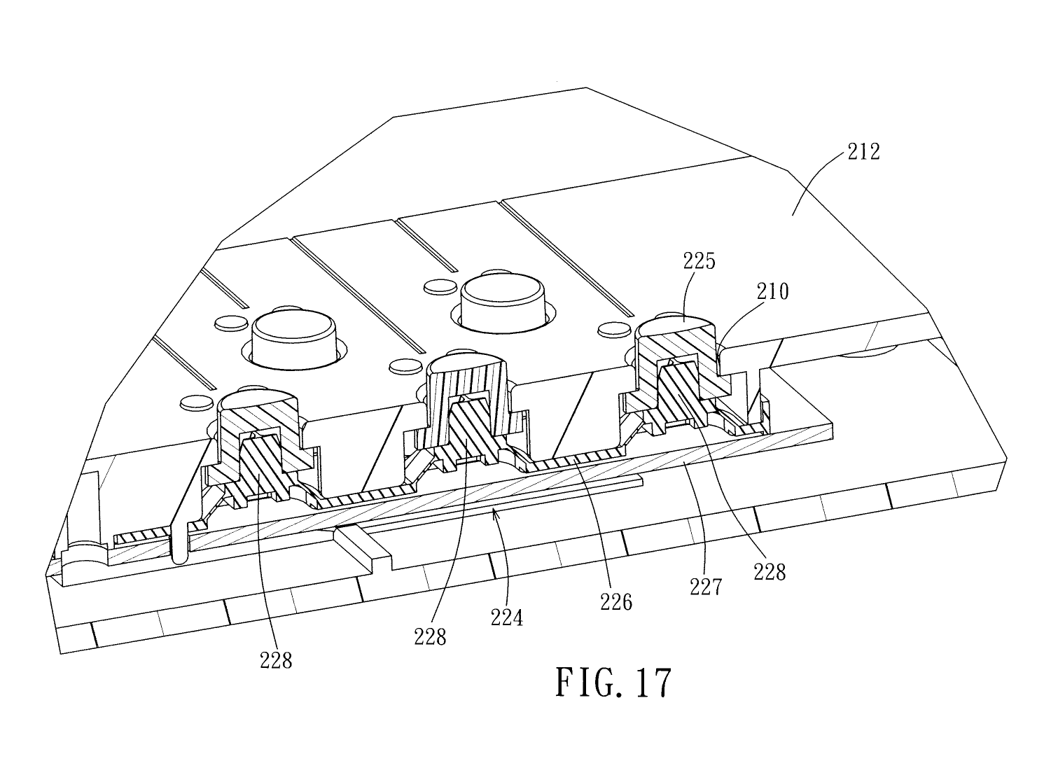

Referring to FIGS. 13, 14, and 17, the screen body 21 further includes a keypad module 224 assembled to an inner surface of the panel 212. The keypad module 224 includes a plurality of keys 225, a rubber pad 226, and a circuit board 227. The keys 225 correspond in number to through holes 210 formed in the panel 212, and each of the keys 225 has a top portion extending through a respective one of the through holes 210. The rubber pad 226 is provided with a plurality of fitting portions 228 on which the keys 225 can be respectively fitted. By means of the circuit board 227 that abuts against a bottom side of the rubber pad 226 and that is secured to the inner surface of the panel 212, the keys 225 can be respectively positioned in the through holes 210. Since the keypad module 224 is assembled to the inner surface of the panel 212, when the panel 212 is removed from the casing 211, the keypad module 224 will be removed together with the panel 212. In practice, if it is required to change the number and positions of the keys 225 of the keypad module 224, a panel 212 of the desired design may be injection molded by replacing the mold core and the keypad module 224 may be changed. Thus, replacement or change of the panel 212 and the keypad module 224 can be quickly conducted, design flexibility can be enhanced, and manufacturing costs can be lowered.

In sum, in the electronic device 100 according to the embodiment, due to the configuration of the positioning members 17 on the upper surface 111 of the base wall 11 of the base 1, the support member 23 can engage selected ones of the positioning members 17 so as to support and position the screen body 21 stably at an inclined position. Furthermore, by virtue of the design of the first and second engaging members 16, 217, the screen body 21 can be secured stably on the base 1 when in the closed state. In addition, through the arrangement of the positioning hooks 222 and the first hooks 221 on the panel 212 that respectively engage the anchoring members 220 and the second hooks 223 on the casing 211, the panel 212 can be quickly assembled to or removed from the casing 211 to permit easy replacement of the panel 212 with one of a different design.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An electronic device comprising:
a base including an upper surface, and a plurality of positioning members disposed on said upper surface and spaced apart from one another; and
a display screen including a screen body which has one end connected pivotably to said base and which is rotatable relative to said base, and a support member connected pivotably to a rear face of said screen body and rotatable relative to said screen body, said support member having one end connected to said rear face of said screen body, and an opposite end engageable with a selected one of said positioning members.

2. The electronic device of claim 1, wherein said one end of said support member is connected pivotably to said screen body, and each of said positioning members is a stop block projecting from said upper surface of said base, said support member including a projecting block for engaging said selected one of said positioning members.

3. The electronic device of claim 1, wherein said base defines an operation path and a restoring path disposed above and in spatial communication with said operation path, said support member including a guide post movable between said operation path and said restoring path, said guide post being positioned in said operation path when said support member is engaged with said selected one of said positioning members, said base further including a resilient plate disposed at front ends of said operation and restoring paths to provide said guide post with a spring force to spring upwardly to said restoring path.

4. The electronic device of claim 1, wherein said base further includes two sidewalls extending upwardly and respectively from two opposite sides of said upper surface, and two first engaging members disposed respectively on said sidewalls, said screen body including two second engaging members disposed on two opposite sides thereof, each of said second engaging members being engageable removably with a respective one of said first engaging members to position said screen body between said sidewalls.

5. The electronic device of claim 1, wherein each of said first engaging members is one of a curved engaging block and a curved engaging groove, and each of said second engaging members is the other of said curved engaging block and said curved engaging groove.

6. The electronic device of claim 1, wherein said screen body includes a casing connected pivotably to said support member, and a panel coupled to and covering said casing, said casing including a plurality of first hooks disposed on an outer periphery thereof, said panel including a plurality of second hooks disposed on an outer periphery thereof, each of said second hooks being engageable removably with a respective one of said first hooks.

7. The electronic device of claim 6, wherein said screen body further includes a keypad module assembled to an inner surface of said panel, said panel having a plurality of through holes, said keypad module including a plurality of keys corresponding in number to said through holes and extending respectively through said through holes.

8. The electronic device of claim 1, wherein said screen body includes a casing connected pivotably to said support member, and a panel coupled to and covering said casing, said casing having one side provided with a plurality of U-shaped anchoring members projecting outwardly therefrom, and an opposite side provided with a plurality of first hooks, said panel having one side provided with a plurality of positioning hooks, and an opposite side provided with a plurality of second hooks, each of said positioning hooks being engageable removably with a bottom end of a respective one of said anchoring members, each of said second hooks being engageable removably with a respective one of said first hooks.

9. The electronic device of claim 8, wherein said screen body further includes a keypad module assembled to an inner surface of said panel, said panel having a plurality of through holes, said keypad module including a plurality of keys corresponding in number to said through holes and extending respectively through said through holes.

10. The electronic device of claim 1, wherein said display screen further includes a torsion spring disposed on said rear face of said screen body, said torsion spring having two ends respectively abutting against said rear face of said screen body and said support member.

11. The electronic device of claim 3, wherein said display screen further includes a torsion spring disposed on said rear face of said screen body, said torsion spring having two ends respectively abutting against said rear face of said screen body and said support member.

12. The electronic device of claim 2, wherein said base defines an operation path and a restoring path disposed above and in spatial communication with said operation path, said support member including a guide post movable between said operation path and said restoring path, said guide post being positioned in said operation path when said support member is engaged with said selected one of said positioning members, said base further including a resilient plate disposed at front ends of said operation and restoring paths to provide said guide post with a spring force to spring upwardly to said restoring path.

13. The electronic device of claim 12, wherein said base further includes two sidewalls extending upwardly and respectively from two opposite sides of said upper surface, and two first engaging members disposed respectively on said sidewalls, said screen body including two second engaging members disposed on two opposite sides thereof, each of said second engaging members being engageable removably with a respective one of said first engaging members to position said screen body between said sidewalls.

14. The electronic device of claim 13, wherein each of said first engaging members is one of a curved engaging block and a curved engaging groove, and each of said second engaging members is the other of said curved engaging block and said curved engaging groove.

15. The electronic device of claim 13, wherein said screen body includes a casing connected pivotably to said support member, and a panel coupled to and covering said casing, said casing including a plurality of first hooks disposed on an outer periphery thereof, said panel including a plurality of second hooks disposed on an outer periphery thereof, each of said second hooks being engageable removably with a respective one of said first hooks.

16. The electronic device of claim 13, wherein said screen body includes a casing connected pivotably to said support member, and a panel coupled to and covering said casing, said casing having one side provided with a plurality of U-shaped anchoring members projecting outwardly therefrom, and an opposite side provided with a plurality of first hooks, said panel having one side provided with a plurality of positioning hooks, and an opposite side provided with a plurality of second hooks, each of said positioning hooks being engageable removably with a bottom end of a respective one of said anchoring members, each of said second hooks being engageable removably with a respective one of said first hooks.

17. The electronic device of claim 15, wherein said screen body further includes a keypad module assembled to an inner surface of said panel, said panel having a plurality of through holes, said keypad module including a plurality of keys corresponding in number to said through holes and extending respectively through said through holes.

18. The electronic device of claim 16, wherein said screen body further includes a keypad module assembled to an inner surface of said panel, said panel having a plurality of through holes, said keypad module including a plurality of keys corresponding in number to said through holes and extending respectively through said through holes.

19. The electronic device of claim 12, wherein said display screen further includes a torsion spring disposed on said rear face of said screen body, said torsion spring having two ends respectively abutting against said rear face of said screen body and said support member.

20. The electronic device of claim 1, wherein said electronic device is an Internet-based telephone.
